(19) United States
(12) Patent Application Publication
(10) Pub. No.: US 2026/0084558 A1
(43) Pub. Date: Mar. 26, 2026

(54) EnerJet Pro

(71) Applicant: Rasheedah R. Terry, Newark, NJ (US)

(72) Inventor: Rasheedah R. Terry, Newark, NJ (US)

(21) Appl. No.: 19/340,841

(22) Filed: Sep. 25, 2025

Related U.S. Application Data
(60) Provisional application No. 63/698,960, filed on Sep. 25, 2024.

(51) Int. Cl. B60L 53/30; B60L 53/50; B60L 53/66; H02J 3/00; H02J 3/32; H02J 3/38; H05K 7/20

(52) U.S. Cl. CPC B60L 53/30; B60L 53/50; B60L 53/66; H02J 3/007; H02J 3/32; H02J 3/38; B60L 2210/22; H02J 2101/24; H02J 2101/28; H02J 2105/12; H05K 7/2089

(57) ABSTRACT

The present invention relates to a portable Level 2 electric vehicle charging system that integrates an inverter, a modular lithium-ion battery pack and renewable energy compatibility into a compact, weather-resistant housing. The system is configured to operate with an AC 240-volt supply and to deliver selectable power outputs up to 30 kW for rapid charging. The modular battery design allows scalable storage capacities ranging from 10 kWh to 40 kWh enabling both grid-connected and off-grid charging modes. A control system manages power delivery from the grid, the battery pack or renewable energy sources such as solar or wind through integrated charge controllers. The invention further provides hybrid charging capability, communication interfaces for monitoring and control and optional cooling systems to ensure safe operation. The portable design allows flexibility for residential, commercial and emergency use offering a reliable and scalable solution for electric vehicle charging.

### DESCRIPTION OF THE DRAWING

FIG. 1 is a schematic representation of the EnerJet Pro portable charging system 100 illustrating its integration with multiple power sources. The system includes a charging unit 104 which houses the inverter and modular lithium-ion battery assembly. The charging unit 104 is connected through an output port and charging cable 102 to an electric vehicle (not shown). A control interface 107 is positioned on the charging unit for operation and monitoring of the system. The system 100 is configured to receive input power from an external grid 106 via a utility connection and protective switchgear 108. The grid 106 supplies AC 240 volts which can be directed into the charging unit 104 to provide direct charging power or to recharge the internal battery modules. In addition to the grid source the system 100 may also be coupled to a renewable energy source such as a solar array 110. The solar array 110 is connected to a solar charge controller 112 which conditions and regulates the power prior to delivery through input line 111 into the charging unit 104. This arrangement allows the EnerJet Pro system to accept energy from renewable sources thereby enabling sustainable off-grid operation and reducing dependency on conventional grid infrastructure. Through this configuration, FIG. 1 demonstrates the dual-mode operation of the EnerJet Pro system wherein the charging unit 104 can be powered by the electrical grid 106 by renewable solar energy 110, or by its own internal battery modules, thus providing flexibility, portability and energy independence in electric vehicle charging.

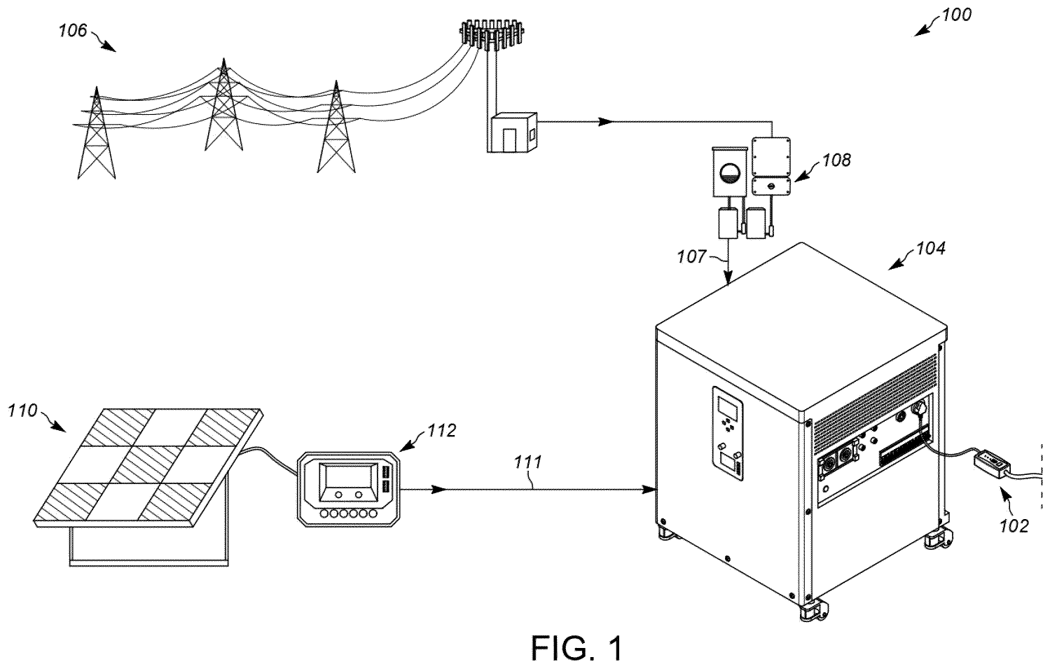

FIG. 2 illustrates an embodiment 200 of the EnerJet Pro portable charging system in operation with an electric vehicle 202. The charging unit 104, which houses the inverter and modular battery assembly is connected to the vehicle 202 through a charging cable 102 that terminates at a vehicle charging port 204. This enables the delivery of regulated charging power from the portable charging system to the electric vehicle battery. The embodiment shown in FIG. 2 further demonstrates integration with an auxiliary renewable energy source located on the vehicle. A solar panel array 110 is mounted on the roof of the vehicle 202 configured to harvest solar energy for supplementary charging. The output of the solar panel array 110 is coupled to a solar charge controller 112 which conditions and regulates the solar energy for safe charging. The solar charge controller 112 is further connected to the portable charging unit 104 to supplement its input power. Through this configuration, the system 200 enables a hybrid charging operation where the vehicle 202 may be charged by the EnerJet Pro unit 104 using either stored battery power, grid-supplied power or solar energy harvested from the vehicle-mounted solar panels 110. This arrangement demonstrates the adaptability of the invention to integrate multiple power sources thereby enhancing charging flexibility and energy independence for the electric vehicle user.

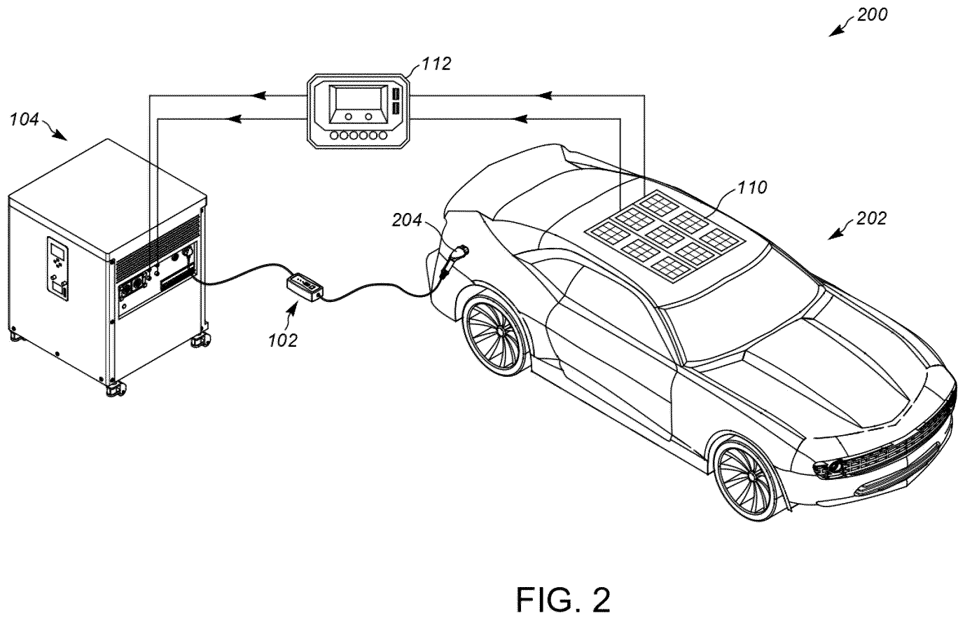

FIG. 3 illustrates another embodiment 300 of the EnerJet Pro portable charging system in connection with an electric vehicle 202. In this embodiment, the charging unit 104 delivers regulated power through the charging cable 102 which is coupled to the vehicle charging port 115 of the electric vehicle 202. The portable charging unit 104 contains the inverter and modular battery pack enabling it to provide Level 2 charging capacity independently or in conjunction with external power sources. The system is further integrated with a solar charge controller 112 which manages the input of renewable energy from solar panels and ensures that solar-derived energy is conditioned before being delivered to either the charging unit 104 or directly to the vehicle charging port 115. The solar charge controller 112 communicates with both the charging unit and the electric vehicle to maintain safe charging conditions and to balance energy distribution. The embodiment also includes a system monitoring and control module 302 which supervises the flow of energy between the charging unit 104, the solar charge controller 112 and the electric vehicle 202. The control module 302 may include sensors, communication interfaces and software logic that optimize charging efficiency, prevent overload and allow user monitoring through a display or connected mobile application. Together, FIG. 3 demonstrates how the EnerJet Pro system 300 operates in a hybrid energy configuration, combining stored energy from the charging unit 104, renewable energy regulated by the solar charge controller 112 and intelligent management provided by the system control module 302 to reliably deliver power to the electric vehicle 202 via the vehicle charging port 115.

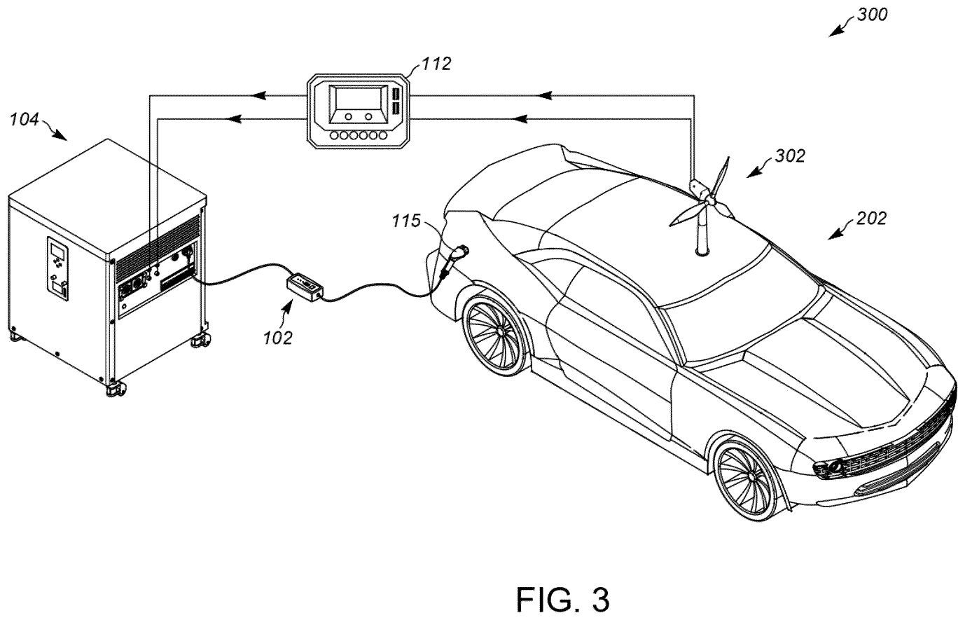

FIG. 4 illustrates an embodiment 400 of the EnerJet Pro portable charging system configured to supply electrical power to a residential structure 402 using renewable energy inputs. The charging unit 104 containing the inverter and modular battery assembly is coupled through charging cables 102 to a solar charge controller 102 positioned externally. The solar charge controller 102 regulates incoming renewable energy and distributes conditioned power to the charging unit 104 and to the residential structure 402. The embodiment incorporates multiple renewable energy sources including a solar array 110 mounted on the roof of the structure 402 and a wind turbine 302 positioned adjacent to the building. Both the solar array 110 and the wind turbine 302 feed into the solar charge controller 102 which balances their outputs and ensures compatibility with the charging system. Conditioned energy from the charge controller may be directed into the charging unit 104 for storage in its modular battery pack or may be delivered directly to the residential structure 402. The residential structure 402 is connected to the charging unit 104 through an output line 404, allowing the stored or converted energy within the EnerJet Pro system to power household loads. This configuration demonstrates how the invention may function not only as a vehicle charging unit but also as a distributed power source for buildings thereby extending its application beyond transportation to residential and commercial energy support. Through this arrangement, FIG. 4 highlights the versatility of the invention in hybrid renewable integration, showing its ability to collect energy from multiple sources such as solar and wind, store that energy in the onboard battery system and distribute it as needed either to an electric vehicle or to a residential power system.

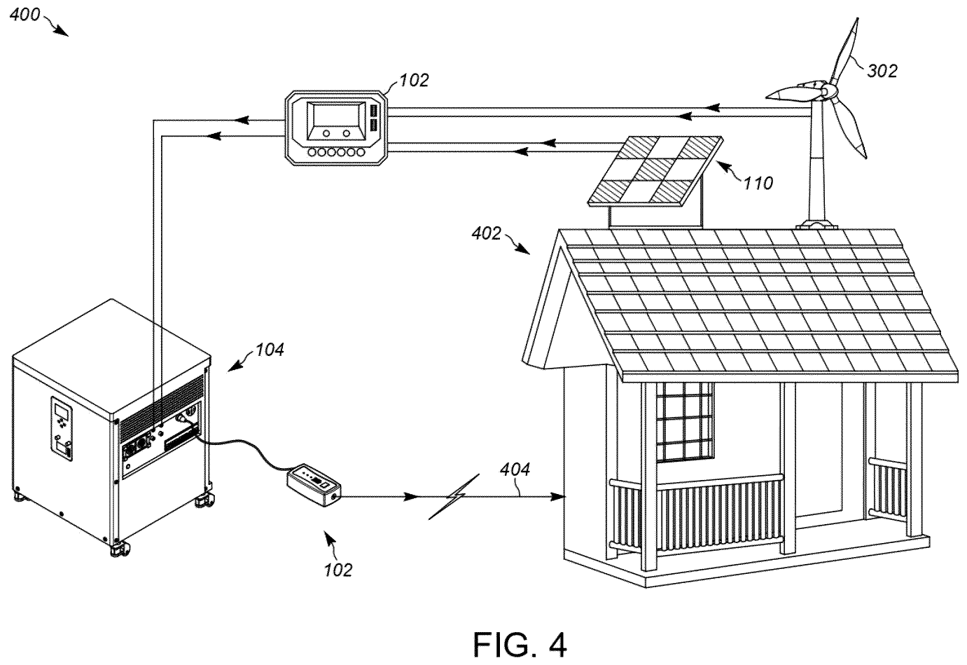

1. A portable electric vehicle charging system comprising:
a weather-resistant housing;
an inverter disposed within the housing and configured to operate with an AC 240-volt supply;
a modular rechargeable lithium-ion battery system disposed within the housing the modular battery system being configurable to provide selectable storage capacities;
a charging cable terminating in a vehicle charging connector configured to couple to a vehicle charging port; and
a control system operatively coupled to the inverter and the modular battery system, the control system being configured to selectively deliver power to the vehicle charging connector from one or more of: the AC 240-volt supply the modular battery system or a renewable energy source.

2. The portable electric vehicle charging system of claim 1, wherein the inverter is selectable to operate at different power output levels including at least one of 12 kW, 15 kW, 20 kW, 25 kW or 30 kW.

3. The portable electric vehicle charging system of claim 1, wherein the modular battery system is configured to provide selectable energy storage capacities of at least one of 10 kWh, 20 kWh, 30 kWh or 40 kWh.

4. The portable electric vehicle charging system of claim 1, wherein the renewable energy source comprises a solar array coupled through a solar charge controller to the control system.

5. The portable electric vehicle charging system of claim 1, wherein the renewable energy source comprises a wind turbine coupled through a charge controller to the control system.

6. The portable electric vehicle charging system of claim 1, wherein the control system is configured to operate in a grid-connected charging mode in which power from the AC 240-volt supply is converted by the inverter for charging a vehicle.

7. The portable electric vehicle charging system of claim 1, wherein the control system is further configured to operate in an off-grid charging mode in which power from the modular battery system is converted by the inverter for charging a vehicle.

8. The portable electric vehicle charging system of claim 1, wherein the control system is configured to operate in a hybrid charging mode in which power from both the AC 240-volt supply and the modular battery system are selectively combined to charge a vehicle.

9. The portable electric vehicle charging system of claim 1, wherein the housing further comprises an integrated cooling system selected from the group consisting of an air-cooled system and a liquid-cooled system.

10. The portable electric vehicle charging system of claim 1, further comprising a monitoring and communication interface configured to provide charge status, system diagnostics, and user control through at least one of a display, a wireless communication module or a mobile application.

11. The portable electric vehicle charging system of claim 1, wherein the system is further configured to supply electrical power to a residential or commercial building through an output connection.
